(19) United States
(12) Patent Application Publication
(10) Pub. No.: US 2021/0095968 A1
(43) Pub. Date: Apr. 1, 2021

(54) INFRASTRUCTURE CHARACTERISTICS BASED MOBILE DEVICE NAVIGATION

(71) Applicant: MAPSTED CORP., Mississauga (CA)

(72) Inventors: Joshua Karon, Toronto (CA); Sean Huberman, Guelph (CA)

(21) Appl. No.: 16/587,392

(22) Filed: Sep. 30, 2019

(51) Int. Cl. G01C 21/20; G01S 5/02; G01R 33/10

(52) U.S. Cl. CPC G01C 21/206; G01S 5/0257; G01R 33/10; G01S 5/0252

(57) ABSTRACT

A method and system of infrastructure based mobile device navigation of an indoor area. The method, executed in a processor of a server computing device, comprises classifying, responsive to accessing an infrastructure map of the indoor area, the indoor area into a first and an at least a second infrastructure regions; localizing a mobile device within the first infrastructure region in accordance with a first positioning algorithm; and switching, responsive to identifying the mobile device within the at least a second infrastructure region, from the first positioning algorithm to an at least a second positioning algorithm as basis for localizing the mobile device.

### TECHNICAL FIELD

The disclosure herein relates to the field of mobile device navigation and positioning.

### BACKGROUND

Users of mobile devices are increasingly using and depending upon indoor positioning and navigation applications and features. Seamless, accurate and dependable indoor positioning can be difficult to achieve using satellite-based navigation systems when the latter becomes unavailable or sporadically available, such as within enclosed or partly enclosed urban infrastructure and buildings, including hospitals, shopping malls, airports, universities and industrial warehouses. To address this problem, indoor navigation solutions increasingly rely on sensors received signal strength (RSS) sensors, magnetometers and inertial sensors including accelerometers, gyroscopes, which may be commonly included in mobile phones and other mobile devices.

### BRIEF DESCRIPTION OF THE DRAWINGS

FIG. 1 illustrates, in an example embodiment, a system for infrastructure characteristics based mobile device navigation in an indoor area;

FIG. 2 illustrates an example architecture of a mobile device for infrastructure characteristics based mobile device navigation;

FIG. 3 illustrates an example architecture of a server computing device for infrastructure characteristics based mobile device navigation;

FIG. 4 illustrates example infrastructure classifications as applied to an indoor infrastructure physical layout; and

FIG. 5 illustrates, in an example embodiment, a method of operation of infrastructure characteristics based mobile device navigation.

### DETAILED DESCRIPTION

The majority of indoor navigation systems require some form of system calibration prior to going live upon deployment. The most typical type of calibration for positioning, also referred to herein as navigation, is fingerprinting. The term fingerprint, variously referred to herein as calibration fingerprint, fingerprint map and fingerprint data, in one embodiment constitutes any combination of time-correlated, individual measurements of received wireless communication signal strength information (RSS), magnetic field information (strength, direction, dip angle) or barometric pressure information at known, fixed locations within an area, including an indoor area. In other words, a fingerprint includes a correlation of sensor and signal information, including, but not necessarily limited to wireless signal strength, magnetic, barometric and inertial sensor information, at a given instance in time, at a unique position along a sequence of positions that constitute a navigation path traversed by the mobile device. Additionally, given that sampling times and sampling rates applied to particular device sensors may be different, the signal and sensor information as measured may be time-averaged across particular periods of time, with the time-averaged value being used to represent the signal and sensor information at any given instance of time within that particular period of time in which the signal information is time-averaged.

Among other benefits and technical effect, embodiments herein provide improved accuracy of indoor positioning systems and improved positioning performance for indoor spaces that include areas with contrasting infrastructure features and conditions. In embodiments, building infrastructure and floorplan data are used to classify sub-areas or regions within the indoor area according to their infrastructure and related logistical characteristics. For example, large open areas and long narrow areas would be classified into different and separate categories. Indoor positioning algorithms are then customized in real time according to the characteristics of the region that the user is currently in.

Optimal indoor positioning is achieved when positioning algorithms are curated to the particular characteristics of an indoor space. For example, an indoor positioning system operating in a narrow hallway will perform better if it relies more heavily on magnetic field measurements, rather than received signal strength (RSS) measurements. This is because magnetic field measurements are generally more unique and more accurate than RSS measurements. However, because magnetic measurements are so unique, if a user deviates from the path where the measurements were taken the matching system can fail. When the user's movement is constrained to a narrow hallway the possibility of deviating from the measured path is minimized and this context is more amenable to magnetics based fingerprint positioning.

Conversely, large open areas perform better when the positioning algorithm relies more heavily on RSS measurements rather than magnetic field measurements, because the user motion is not constrained along a path where the calibration or reference magnetic measurements were recorded. Therefore, positioning based on magnetic measurements can become significantly less accurate and less useful in large open areas, whereas RSS based fingerprint positioning provides superior results in such context.

An additional challenge occurs when an indoor space contains areas of contrasting environmental characteristics. For example, most malls are made up of long narrow hallways and large junction areas where the hallways intersect. The optimal positioning algorithm used for a hallway is not the same as the optimal positioning algorithm used for a junction and vice versa.

Provided herein is a method and system of infrastructure characteristics based mobile device navigation within an indoor area. The method, executed in a processor of a server computing device, comprises classifying, responsive to accessing an infrastructure map of the indoor area, the indoor area into a first and an at least a second infrastructure regions; localizing a mobile device within the first infrastructure region in accordance with a first positioning algorithm; and switching, responsive to identifying the mobile device within the at least a second infrastructure region, from the first positioning algorithm to an at least a second positioning algorithm as basis for localizing the mobile device.

Also provided is a server computing system for infrastructure characteristics based mobile device navigation within an indoor area. The server includes a processor and a memory. The memory includes instructions executable in the processor to classify, responsive to accessing an infrastructure map of the indoor area, the indoor area into a first and an at least a second infrastructure regions; localize a mobile device within the first infrastructure region in accordance with a first positioning algorithm; and switch, responsive to identifying the mobile device within the at least a second infrastructure region, from the first positioning algorithm to an at least a second positioning algorithm as basis for localizing the mobile device.

One or more embodiments described herein provide that methods, techniques, and actions performed by a computing device are performed programmatically, or as a computer-implemented method. Programmatically, as used herein, means through the use of code or computer-executable instructions. These instructions can be stored in one or more memory resources of the computing device. A programmatically performed step may or may not be automatic.

One or more embodiments described herein can be implemented using programmatic modules, engines, or components. A programmatic module, engine, or component can include a program, a sub-routine, a portion of a program, or a software component or a hardware component capable of performing one or more stated tasks or functions. As used herein, a module or component can exist on a hardware component independently of other modules or components. Alternatively, a module or component can be a shared element or process of other modules, programs or machines.

Some embodiments described herein can generally require the use of computing devices, including processor and memory resources. For example, one or more embodiments described herein may be implemented, in whole or in part, on computing devices such as servers, desktop computers, mobile devices including cellular or smartphones, laptop computers, wearable devices, and tablet devices. Memory, processing, and network resources may all be used in connection with the establishment, use, or performance of any embodiment described herein, including with the performance of any method or with the implementation of any system.

Furthermore, one or more embodiments described herein may be implemented through the use of instructions that are executable by one or more processors. These instructions may be carried on a computer-readable medium. Machines shown or described with figures below provide examples of processing resources and computer-readable mediums on which instructions for implementing embodiments of the invention can be carried and/or executed. In particular, the numerous machines shown with embodiments of the invention include processor(s) and various forms of memory for holding data and instructions. Examples of computer-readable mediums include permanent memory storage devices, such as hard drives on personal computers or servers. Other examples of computer storage mediums include portable memory storage units, flash memory (such as carried on smartphones, multifunctional devices or tablets), and magnetic memory. Computers, terminals, network enabled devices (e.g., mobile devices, such as cell phones) are all examples of machines and devices that utilize processors, memory, and instructions stored on computer-readable mediums. Additionally, embodiments may be implemented in the form of computer-programs, or a computer usable carrier medium capable of carrying such a program.

### System Description

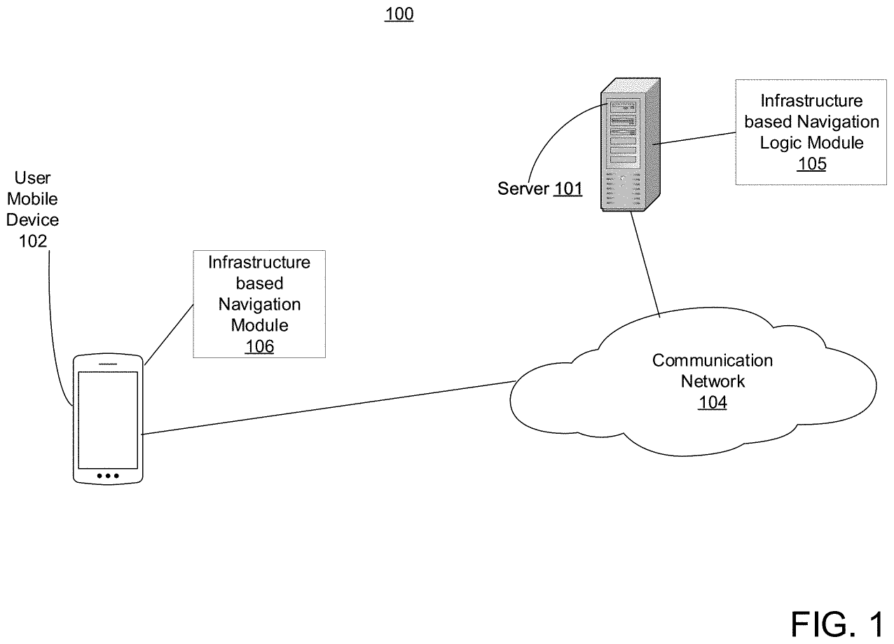

FIG. 1 illustrates, in an example embodiment, a system 100 for infrastructure characteristics based mobile device navigation in an indoor area. Server computing device 101, also referred to herein as server 101, includes infrastructure based navigation logic module 105, and is communicatively connected via communication network 104 to a plurality of computing and communication mobile device 102, also referred to herein as mobile device 102. Mobile device 102 include infrastructure based navigation module 106, which in one embodiment, may be included in an indoor positioning, or indoor navigation, software application downloaded and installed at mobile device 102.

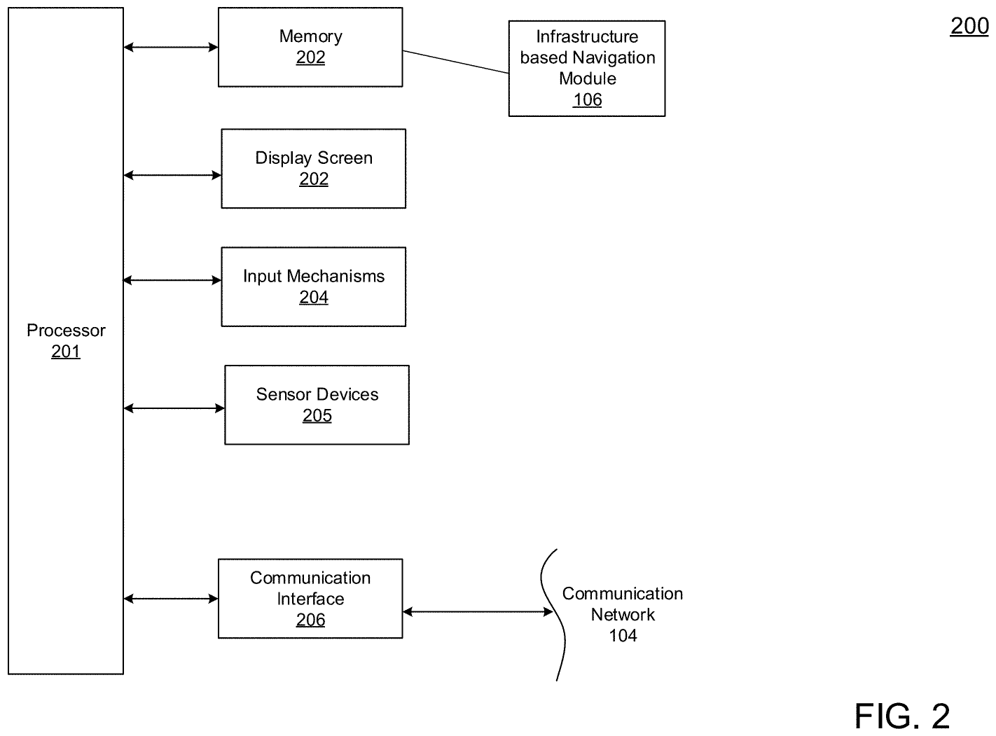

FIG. 2 illustrates an example architecture 200 of a mobile device for infrastructure characteristics based mobile device navigation. As used herein, the term mobile device 102 refers to any singular mobile device among mobile device 102. In one embodiment, mobile device 102 may correspond to, for example, a cellular communication device (e.g., smartphone, tablet, etc.) that is capable of telephony, messaging, and/or data computing services. In variations, mobile device 102 can correspond to, for example, a tablet or a wearable computing device. Mobile device 102 may include processor 201, memory 202, display screen 203, input mechanisms 204 such as a keyboard or software-implemented touchscreen input functionality, barcode, QR code or other symbol- or code-scanner input functionality. Mobile device 102 may include sensor functionality by way of sensor devices 205. Sensor devices 205 may include any of inertial sensors (accelerometer, gyroscope), magnetometer or other magnetic field sensing functionality, barometric or other environmental pressure sensing functionality, and received signal strength (RSS) sensors relating to wireless communication signals. Mobile device 102 may also include capability for detecting and communicatively accessing wireless communication signals, including but not limited to any of Bluetooth, Wi-Fi, RFID, and GPS signals. Mobile device 102 further includes the capability for detecting and measuring a received signal strength of the wireless communication signals. In particular, mobile device 102 may include location determination capability such as by way of GPS module 205, and communication interface 206 for communicatively coupling to communication network 104, such as by sending and receiving cellular data over data channels and voice channels.

Infrastructure based navigation module 106 includes instructions stored in memory 202 of mobile device 102. In embodiments, infrastructure based navigation module 106 may be included in a mobile device navigation application program stored in memory 202 of mobile device 102 for acquiring fingerprint data within an area by any of plurality of mobile device 102. The area may be an indoor area within a shopping mall, an airport, a warehouse, a university, or any at least partially enclosed building. Acquisition of the fingerprint data may be automatically triggered at respective ones of mobile device 102 upon an event occurrence. The event occurrence may consist of a user of mobile device 102 redeeming a promotion coupon at a merchant within a shopping mall, scanning a barcode, using an RFID tag, or upon the mobile device 102 becoming present at specific predetermined locations within the area. The occurrence event may be also based on detecting an access point wireless signal as deployed in indoor infrastructure, in some examples. Acquisition of the fingerprint data by a user's mobile device 102 may thus be automatically triggered upon the event occurrence at any predetermined set of fixed positions within the area.

The terms fingerprint and fingerprint data as used herein refer to time-correlated, time-stamped individual measurements of any of, or any combination of, received wireless communication signal strength or RSS parameters, and signal connectivity parameters, magnetic field parameters (strength, direction, dip angle) or barometric pressure parameters, and mobile device inertial sensor data at known, particular locations along a route being traversed, and also anticipated for traversal, by the mobile device. In other words, a fingerprint as referred to herein may include a correlation of sensor and signal information (including, but not necessarily limited to wireless signal strength, wireless connectivity information, magnetic or barometric information, inertial sensor information and GPS location information) associated for a unique location relative to the facility in accordance with a particular time stamp of gathering the set of mobile sensor data by time correlating the mobile device gyroscope data, the mobile device accelerometer data, mobile device magnetometer data and any other applicable mobile device sensor data, for example. Thus, fingerprint data associated with a particular location or position may provide a fingerprint signature that uniquely correlates to that particular location or position. A sequence of positions or locations that constitute a navigation path traversed by the mobile device relative to a given indoor facility may be fingerprint-mapped during a calibration process, and the resulting fingerprint map stored in a fingerprint data repository of server 101. Server 101 may store respective fingerprint maps of various buildings and indoor areas. The respective building or indoor facility fingerprint maps, or any portions thereof, may be downloaded into a memory of mobile device 102 for use in conjunction with the pedestrian navigation software application executing thereon.

In embodiments, magnetic fingerprint information of the fingerprint map is susceptible to frequent changes encountered in an indoor navigation environment. The magnetic characteristics of the earth's magnetic field may vary in different zones of a given building given the presence of steel structural elements, ferromagnetic objects and the electronic equipment typically contained there. Such elements perturb the earth's magnetic field which may provide the potential for distinguishing unique locations or positions inside the buildings. In general, a non-uniform indoor ambient magnetic field produces different magnetic observations depending on the path taken through it. Static objects or infrastructures inside buildings, such as steel structures, electric power systems and electronic and mechanical appliances, perturb the earth's magnetic field in a manner that establishes a profile of magnetic field values that constitute a map composed of magnetic field fingerprints. Certain elements inside buildings can distort or attenuate the relatively weak direction of the earth's magnetic field. Magnetic field perturbation as sensed or measured at a given location, for example by way of one or more of a magnetic field strength, a magnetic direction and a magnetic angle, within the building may decrease rapidly as the distance from an interfering source increases. The size of the object responsible for the interference has a direct impact on the perturbation generated. More specifically, the larger the object, the greater the distance needed for the perturbation to decrease. It is contemplated that such changes over time may adversely affect the accuracy of magnetic fingerprint calibration data, and thus affect the accuracy of positioning results in mobile device navigation.

In embodiments, viability of an existing magnetic fingerprint map may be highly dependent on the infrastructure floor layout of an indoor area.

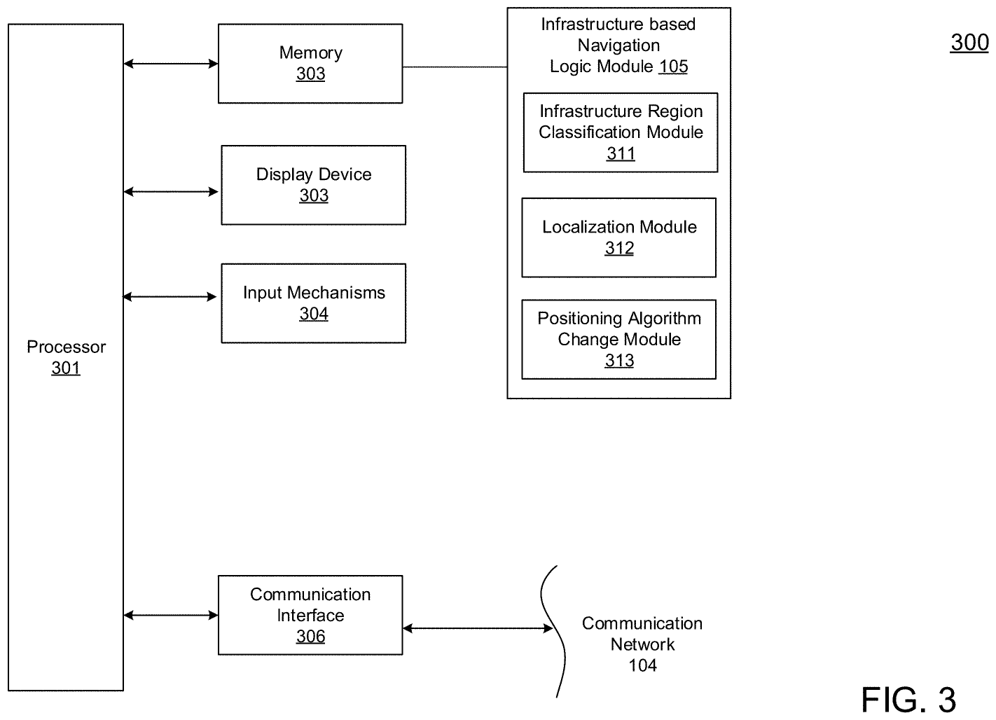

FIG. 3 illustrates an example architecture 300 of a server computing device for infrastructure characteristics based mobile device navigation. Server 101, in an embodiment architecture, may be implemented on one or more server devices, and includes processor 301, memory 302 which may include a read-only memory (ROM) as well as a random access memory (RAM) or other dynamic storage device, display device 303, input mechanisms 304 and communication interface 306 for communicative coupling to communication network 104. Processor 301 is configured with software and/or other logic, such as from infrastructure based navigation logic module 105, to perform one or more processes, steps and other functions described with implementations, such as described by FIGS. 1 through 5 herein. Processor 301 may process information and instructions stored in memory 302, such as provided by a random access memory (RAM) or other dynamic storage device, for storing information and instructions which are executable by processor 301. Memory 302 also may be used for storing temporary variables or other intermediate information during execution of instructions to be executed by processor 301. Memory 302 may also include the ROM or other static storage device for storing static information and instructions for processor 301; a storage device, such as a magnetic disk or optical disk, may be provided for storing information and instructions. Communication interface 306 enables server 101 to communicate with one or more communication networks 104 (e.g., cellular network) through use of the network link (wireless or wired). Using the network link, server 101 can communicate with computing devices 102a-n.

Infrastructure based navigation logic module 105, of server 101 may include instructions stored in RAM of memory 302, and includes infrastructure region classification module 311, Localization module 312, and positioning algorithm change module 313.

Processor 301 uses executable instructions stored in infrastructure region classification module 311 to classify, responsive to accessing an infrastructure map of the indoor area, the indoor area into a first and an at least a second infrastructure regions. The area may be an indoor area within a shopping mall, an airport, a warehouse, a university, or any at least partially enclosed building. In embodiments, the fingerprint data, as acquired from mobile device 102, further includes respective time-stamps, whereby the orientation, the magnetic field strength and direction, the received wireless signal strength, the barometric pressure, and the position data can be time-correlated for any given position along a trajectory or trajectory segment of the mobile devices, in accordance with the respective time-stamps. Additionally, when the sampling times and sampling rates applied to particular ones of device sensors 205 are different, the signal and sensor information as measured may be time-averaged across particular periods of time, with the time-averaged value being used to represent the signal information at any given instance of time within that particular period of time in which the signal information is time-averaged.

Processor 301 uses executable instructions stored in localization module 312 to localizing a mobile device within the first infrastructure region in accordance with a first positioning algorithm. The terms localize or localizing as used herein refer determining a coordinate location of the mobile device and may be expressed in local or global (X, Y) coordinate terms. In some embodiments, the coordinates may further include a Z coordinate representing a height, for example associated with a given floor within a multi-floor building, and thus expressed in (X, Y, Z) coordinate terms. Further processing, via the instructions constituting Localization module 312 executable in processor 301, may apply for a second set of fingerprint data and the calibrated data points to generate an updated distribution of calibrated data points. The processing to generate the distribution of calibrated data points may include matching the fingerprint data based at least partly on the correlations, amalgamating the matched data from respective ones of the plurality of mobile device 102 and any additional mobile devices into a cumulative calibration dataset. Then generating, based on the cumulative calibration dataset, the distribution of calibrated data points mapped to respective positions within the area.

Processor 301 uses executable instructions stored in positioning algorithm change module 313 to switch, responsive to identifying the mobile device within the at least a second infrastructure region, from the first positioning algorithm to an at least a second positioning algorithm as basis for localizing the mobile device.

In embodiments, the first positioning algorithm is based primarily on a magnetic fingerprint map that comprises a magnetic field measurement at respective ones of a plurality of locations within the indoor area, and wherein the magnetic field measurement is at least one of a magnetic field strength, a magnetic direction and a magnetic dip angle.

In embodiments, the at least a second infrastructure region comprises one of a hall and a dimensionally unrestrictive area.

In embodiments, the at least a second positioning algorithm is based primarily on a received signal strength (RSS) fingerprint map that comprises a RSS measurement at respective ones of a plurality of locations within the indoor area.

In embodiments, the first positioning algorithm comprises an increased weighting of the magnetic fingerprint map relative to the RSS fingerprint map.

In embodiments, the at least a second positioning algorithm comprises an increased weighting of the RSS fingerprint map relative to the magnetic fingerprint map.

In embodiments, the infrastructure map of the indoor area comprises a floor layout of the indoor area that delineates at least one of a wall, a pedestrian path, a corridor, a room, a building access doorway, an elevator, an escalator and an assembly area.

In embodiments, the floor layout comprises a multi-floor layout.

In embodiments, the switching comprises, as basis for localizing the mobile device within the indoor area, terminating the first positioning algorithm and initiating the at least a second positioning algorithm.

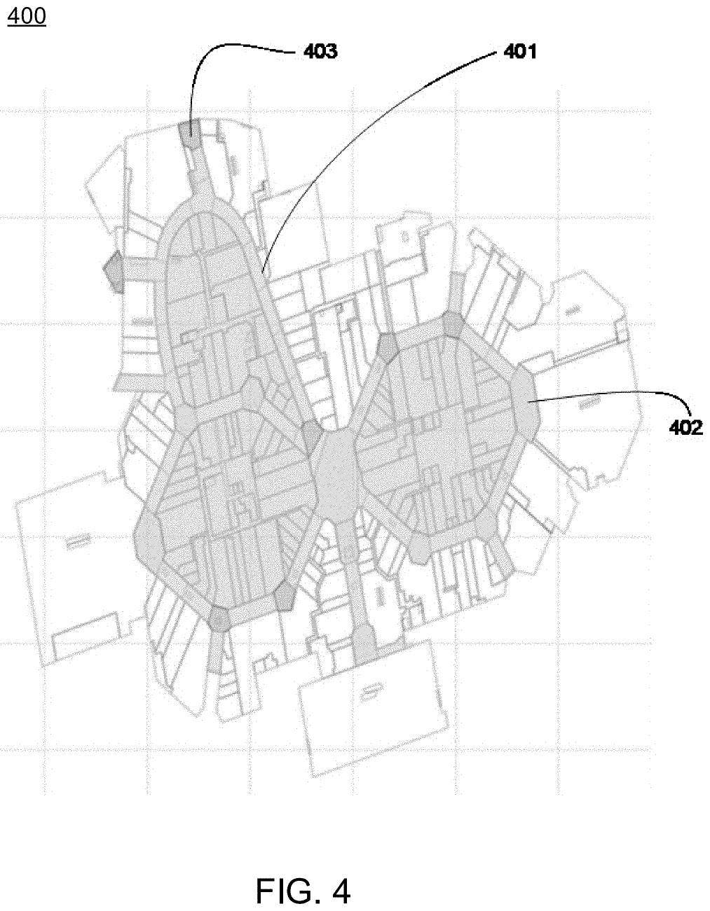

FIG. 4 illustrates example infrastructure classifications as applied to an indoor infrastructure physical floor layout 400. In this embodiment, areas within a mall are classified into three categories:
Narrow hallways 401
Small wide areas 403
Large wide areas 402
   The real-time positioning algorithms are curated and applied as follows:

| | |
|---|---|
| Narrow | In these areas magnetic field is a strong |
| hallways 401 | indicator of position and it will play a more |
| | significant role in the algorithm in |
| | comparison to RSS measurements, additionally |
| | the predicted motion of the user would more |
| | likely be up or down the length of the hallway |
| | and movement across the hallway is less likely. |
| Small wide | In these areas magnetic field measurements are |
| areas 403 | less valuable than they are in hallways and will |
| | have less weight in relation to the RSS measurements. |
| | Additionally, the predicted user motion will be |
| | from one connected hallway to another seeing as there |
| | are not usually any reason for a user to remain |
| | in the small wide areas. |
| Large wide | In these areas magnetic measurements have little |
| areas 402 | value and the positioning will be driven by the |
| | RSS measurements. Unlike the other cases, the |
| | predicted user motion will not follow a strict |
| | pattern, rather the user motion will be predicted |
| | to go in all directions seeing as the user is not |
| | restricted and often large areas have attractions |
| | that would allow a user to remain in the center |
| | of the area, such as a food court. |

### Methodology

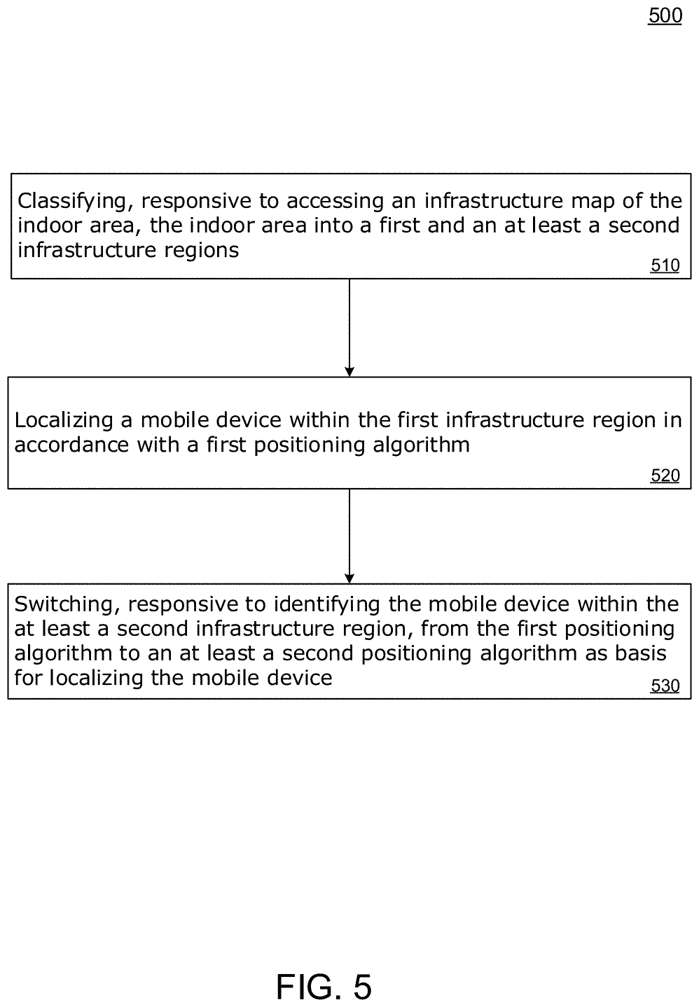

FIG. 5 illustrates, in an example embodiment, a method 500 of operation of infrastructure characteristics based mobile device navigation. In describing examples of FIG. 5, reference is made to the examples of FIGS. 1-3 for purposes of illustrating suitable components or elements for performing a step or sub-step being described.

Examples of method steps described herein are related to the use of server 101, variously referred to herein as server 101, for implementing the techniques described herein. According to one embodiment, the techniques are performed by infrastructure based navigation logic module 105, of server 101 in response to the processor 301 executing one or more sequences of software logic instructions that constitute infrastructure based navigation logic module 105. In embodiments, infrastructure based navigation logic module 105 may include the one or more sequences of instructions within sub-modules including infrastructure region classification module 311, Localization module 312 and positioning algorithm change module 313. Such instructions may be read into memory 302 from machine-readable medium, such as memory storage devices. Execution of the sequences of instructions contained in infrastructure region classification module 311, Localization module 312 and positioning algorithm change module 313 of infrastructure based navigation logic module 105 in memory 302 causes processor 301 to perform the process steps described herein. In alternative implementations, at least some hard-wired circuitry may be used in place of, or in combination with, the software logic instructions to implement examples described herein. Thus, the examples described herein are not limited to any particular combination of hardware circuitry and software instructions.

At step 510, classifying, responsive to accessing an infrastructure map of the indoor area, the indoor area into a first and an at least a second infrastructure regions. The indoor area may be a shopping mall, an airport, a warehouse, a university, a hospital, a conference hall, an exhibition hall or any at least partially enclosed building

At step 520, localizing a mobile device within the first infrastructure region in accordance with a first positioning algorithm. The fingerprint map data may be acquired using sensor devices 205 of the mobile devices, including but not limited to an accelerometer, a gyroscope, a magnetometer, a barometer, and a wireless signal strength sensor. The fingerprint map data may include measured values of an orientation, a magnetic field strength and direction, a magnetic dip angle, a received wireless signal strength, a barometric pressure, at a given position within the area for respective mobile devices.

In embodiments, the fingerprint data, as acquired from the mobile devices, further includes respective time-stamps, whereby the orientation and other inertial sensor data, the magnetic field strength and direction, the received wireless signal strength, the barometric pressure, and the position data can be time-correlated with respect to any given position along a trajectory or trajectory segment of the mobile devices, in accordance with the respective time-stamps. Additionally, given that sampling times and sampling rates applied to particular ones of device sensors 205 may be different, the signal and sensor information as measured may be time-averaged across particular periods of time, with the time-averaged value being used to represent the signal information at any given instance of time within that particular period of time in which the signal information is time-averaged.

At step 530, switching, responsive to identifying the mobile device within the at least a second infrastructure region, from the first positioning algorithm to an at least a second positioning algorithm as basis for localizing the mobile device.

In embodiments, the first positioning algorithm is based primarily on a magnetic fingerprint map that comprises a magnetic field measurement at respective ones of a plurality of locations within the indoor area, and wherein the magnetic field measurement is at least one of a magnetic field strength, a magnetic direction and a magnetic dip angle.

In embodiments, the at least a second infrastructure region comprises one of a hall and a dimensionally unrestrictive area.

In embodiments, the at least a second positioning algorithm is based primarily on a received signal strength (RSS) fingerprint map that comprises a RSS measurement at respective ones of a plurality of locations within the indoor area.

In embodiments, the first positioning algorithm comprises an increased weighting of the magnetic fingerprint map relative to the RSS fingerprint map.

In embodiments, the at least a second positioning algorithm comprises an increased weighting of the RSS fingerprint map relative to the magnetic fingerprint map.

In embodiments, the infrastructure map of the indoor area comprises a floor layout of the indoor area that delineates at least one of a wall, a pedestrian path, a corridor, a room, a building access doorway, an elevator, an escalator and an assembly area.

In embodiments, the floor layout comprises a multi-floor layout.

In embodiments, the switching comprises, as basis for localizing the mobile device within the indoor area, terminating the first positioning algorithm and initiating the at least a second positioning algorithm.

In embodiments, the magnetic field measurement is at least one of a magnetic field strength, a magnetic direction and a magnetic dip angle.

In embodiments, the magnetic field measurement is obtained at least in part based on a magnetometer device.

In embodiments, the magnetic fingerprint map and the RSS fingerprint map include respective time-stamps, whereby measurements of magnetic field strength, direction, dip angle and received wireless signal strength include correlations in accordance with the respective time-stamps.

It is contemplated for embodiments described herein to extend to individual elements and concepts described herein, independently of other concepts, ideas or system, as well as for embodiments to include combinations of elements recited anywhere in this application. Although embodiments are described in detail herein with reference to the accompanying drawings, it is to be understood that the invention is not limited to those precise embodiments. As such, many modifications and variations will be apparent to practitioners skilled in this art. Accordingly, it is intended that the scope of the invention be defined by the following claims and their equivalents. Furthermore, it is contemplated that a particular feature described either individually or as part of an embodiment can be combined with other individually described features, or parts of other embodiments, even if the other features and embodiments make no mention of the particular feature. Thus, the absence of describing combinations should not preclude the inventor from claiming rights to such combinations.

What is claimed is:

1. A method for infrastructure based mobile device navigation in an indoor area, the method executed in a processor of a server computing device and comprising:
classifying, responsive to accessing an infrastructure map of the indoor area, the indoor area into a first and an at least a second infrastructure regions;
localizing a mobile device within the first infrastructure region in accordance with a first positioning algorithm; and
switching, responsive to identifying the mobile device within the at least a second infrastructure region, from the first positioning algorithm to an at least a second positioning algorithm as basis for localizing the mobile device.

2. The method of claim 1 wherein the first infrastructure region comprises one of a hallway, a corridor, a passageway, and a laterally restricted pathway.

3. The method of claim 2 wherein the first positioning algorithm is based primarily on a magnetic fingerprint map that comprises a magnetic field measurement at respective ones of a plurality of locations within the indoor area, and wherein the magnetic field measurement is at least one of a magnetic field strength, a magnetic direction and a magnetic dip angle.

4. The method of claim 3 wherein the at least a second infrastructure region comprises one of a hall and a dimensionally unrestrictive area.

5. The method of claim 4 wherein the at least a second positioning algorithm is based primarily on a received signal strength (RSS) fingerprint map that comprises a RSS measurement at respective ones of a plurality of locations within the indoor area.

6. The method of claim 5 wherein the first positioning algorithm comprises an increased weighting of the magnetic fingerprint map relative to the RSS fingerprint map.

7. The method of claim 5 wherein the at least a second positioning algorithm comprises an increased weighting of the RSS fingerprint map relative to the magnetic fingerprint map.

8. The method of claim 7 wherein the infrastructure map of the indoor area comprises a floor layout of the indoor area that delineates at least one of a wall, a pedestrian path, a corridor, a room, a building access doorway, an elevator, an escalator and an assembly area.

9. The method of claim 8 wherein the floor layout comprises a multi-floor layout.

10. The method of claim 1 wherein the switching comprises, as basis for localizing the mobile device within the indoor area, terminating the first positioning algorithm and initiating the at least a second positioning algorithm.

11. A server computing system for deploying a calibrated positioning map of an area, the server system comprising:
a processor;
a memory storing a set of instructions, the instructions executable in the processor to:
classify, responsive to accessing an infrastructure map of the indoor area, the indoor area into a first and an at least a second infrastructure regions;
localize a mobile device within the first infrastructure region in accordance with a first positioning algorithm; and
switch, responsive to identifying the mobile device within the at least a second infrastructure region, from the first positioning algorithm to an at least a second positioning algorithm as basis for localizing the mobile device.

12. The system of claim 11 wherein the first infrastructure region comprises one of a hallway, a corridor, a passageway, and a laterally restricted pathway.

13. The system of claim 12 wherein the first positioning algorithm is based primarily on a magnetic fingerprint map that comprises a magnetic field measurement at respective ones of a plurality of locations within the indoor area, and wherein the magnetic field measurement is at least one of a magnetic field strength, a magnetic direction and a magnetic dip angle.

14. The system of claim 13 wherein the at least a second infrastructure region comprises one of a hall and a dimensionally unrestrictive area.

15. The system of claim 14 wherein the at least a second positioning algorithm is based primarily on a received signal strength (RSS) fingerprint map that comprises a RSS measurement at respective ones of a plurality of locations within the indoor area.

16. The method of claim 15 wherein the first positioning algorithm comprises an increased weighting of the magnetic fingerprint map relative to the RSS fingerprint map.

17. The system of claim 15 wherein the at least a second positioning algorithm comprises an increased weighting of the RSS fingerprint map relative to the magnetic fingerprint map.

18. The system of claim 17 wherein the infrastructure map of the indoor area comprises a floor layout of the indoor area that delineates at least one of a wall, a pedestrian path, a corridor, a room, a building access doorway, an elevator, an escalator and an assembly area.

19. The system of claim 18 wherein the floor layout comprises a multi-floor layout.

20. The system of claim 11 wherein the switching comprises, as basis for localizing the mobile device within the indoor area, terminating the first positioning algorithm and initiating the at least a second positioning algorithm.
